(19) United States
(12) Patent Application Publication
(10) Pub. No.: US 2025/0108351 A1
(43) Pub. Date: Apr. 3, 2025

(54) VAPORIZER AND VAPORIZING SYSTEM

(71) Applicant: HORIBA STEC, Co., Ltd., Kyoto-shi (JP)

(72) Inventors: Takashi KANAMARU, Kyoto-shi (JP); Hajime KAWAKADO, Kyoto-shi (JP)

(21) Appl. No.: 18/904,016

(22) Filed: Oct. 1, 2024

(30) Foreign Application Priority Data
Oct. 2, 2023 (JP) 2023-171078

(51) Int. Cl. B01J 7/02

(52) U.S. Cl. CPC B01J 7/02

(57) ABSTRACT

A vaporizer for vaporizing a liquid substance includes: a tank for storing the liquid substance; a heater for heating the liquid substance by heating the tank; and a porous structure, disposed inside the tank, for breaking up and letting pass through it bubbles that form as a result of the liquid substance being heated by the heater.

The present application is based on, and claims priority from, Japanese Patent Application No. 2023-171078, filed on Oct. 2, 2023, the disclosure of which is hereby incorporated by reference herein in its entirety.

### BACKGROUND OF THE INVENTION

### 1. Field of the Invention

The present invention relates to vaporizers and vaporizing systems.

### 2. Description of Related Art

With known baking-type vaporizers, a tank storing a liquid substance is heated with a heater so that the liquid substance is vaporized to produce gas. A baking-type vaporizer of this type is disclosed, for example, in WO 2020/195349.

In a baking-type vaporizer, when the tank is heated, the liquid substance in it boils to form gas bubbles. Formation of gas bubbles causes a change in the pressure inside the tank. This change in pressure may affect the output flow rate from a flow rate control device (also called a mass flow controller) disposed on the secondary side of the tank. For example, a change in the pressure inside the tank may impair the stability of the flow rate. In particular, a small, compact vaporizer has a small tank; formation of gas bubbles is more likely to cause a change in the pressure inside the tank and to impair the stability of the flow rate.

### SUMMARY OF THE INVENTION

Devised to solve the above inconvenience, the present invention is aimed at providing a vaporizer, and a vaporizing system, that can suppress a change in the pressure inside a tank caused by formation of gas bubbles.

According to one aspect of the present invention, a vaporizer for vaporizing a liquid substance includes: a tank for storing the liquid substance; a heater for heating the liquid substance by heating the tank; and a porous structure, disposed inside the tank, for breaking up and letting pass through it bubbles that form as a result of the liquid substance being heated by the heater.

According to another aspect of the present invention, a vaporizing system includes: the vaporizer described above; and a flow rate control device for controlling the flow rate of the gas resulting from the liquid substance being vaporized by the vaporizer.

Other objects of the present invention and specific benefits of the present invention will become clear through the description of its embodiments given below.

### BRIEF DESCRIPTION OF THE DRAWINGS

FIG. 1 is a perspective view schematically showing an outline of the configuration of a vaporizing system according to one embodiment of the present invention.

FIG. 2 is a perspective view schematically showing the configuration of a vaporizer provided in the vaporizing system.

FIG. 3 is a sectional view schematically showing the configuration of the vaporizer.

FIG. 4 is a plan view of a porous structure provided in the vaporizer, showing it as it is before and after being disposed inside the tank.

FIG. 5 is a plan view of another porous structure, showing it as it is before and after being disposed inside the tank.

FIG. 6 is a sectional view schematically showing another configuration of the vaporizer.

FIG. 7 is a perspective view schematically showing a modified example of a bottom plate portion of the tank.

FIG. 8 is a sectional view schematically showing yet another configuration of the vaporizer.

### DETAILED DESCRIPTION OF PREFERRED EMBODIMENTS

An illustrative embodiment of the present invention will be described below with reference to the accompanying drawings. For convenience of description, in the diagrams the bottom-to-top direction with respect to a vaporizing system is taken as Z direction and two directions perpendicular to Z direction that are perpendicular to each other are taken as X and Y directions.

### 1. Configuration of a Vaporizing System

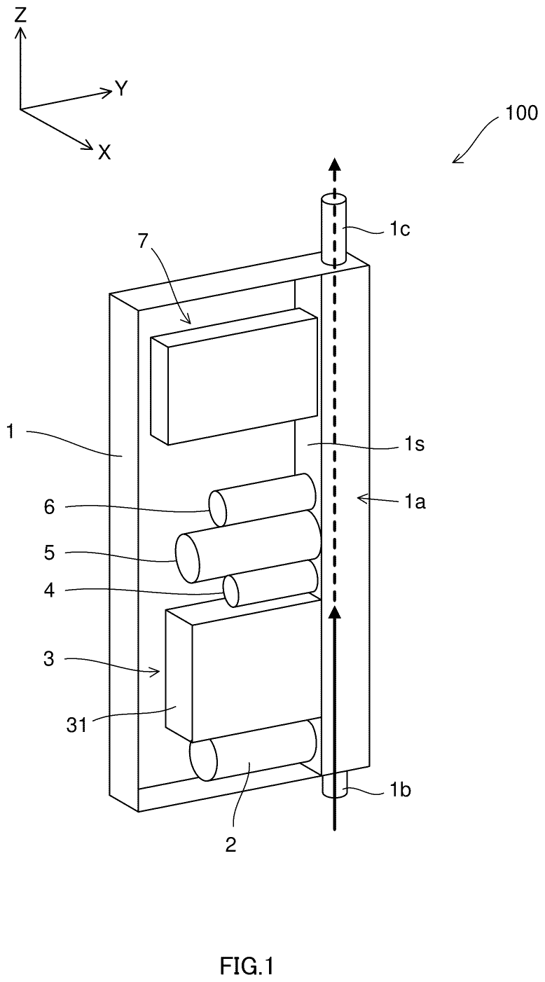

FIG. 1 is a perspective view schematically showing an outline of the configuration of a vaporizing system 100 according to the embodiment. The vaporizing system 100 includes, inside a housing 1 substantially in the shape of a rectangular parallelepiped, a first valve 2, a vaporizer 3, a pressure sensor 4, a second valve 5, a third valve 6, and a flow rate control device 7. Note that FIG. 1 omits illustration of a side wall of the housing 1 at its front to visibly show inside the housing 1.

The first valve 2, the vaporizer 3, the pressure sensor 4, the second valve 5, the third valve 6, and the flow rate control device 7 are fixed to a side face Is of a body block la provided inside the housing 1. The body block la extends along the top-bottom direction inside the housing 1. The body block 1a has formed inside it a flow passage for a liquid substance (hereinafter referred to also as the liquid passage) and a flow passage for gas (hereinafter referred to also as the gas passage). In FIG. 1, the direction of the flow of the liquid substance is indicated by a solid-line arrow and the direction of the flow of the gas is indicated by a broken-line arrow. The liquid substance can be any of various substances that are used in semiconductor production processes.

The first valve 2 is a control valve that controls the flow rate of the liquid substance supplied to the vaporizer 3 (i.e., a liquid substance supply valve) and is configured with, for example, an electromagnetic on-off valve. With the first valve 2 open, the liquid substance is introduced into the body block 1a through a liquid substance supply port 1b located in a bottom part of the body block 1a. The liquid substance introduced is supplied into a tank 31 in the vaporizer 3 through the first valve 2 and the liquid passage inside the body block 1a. By contrast, with the first valve 2 closed, the liquid substance ceases to be supplied to the tank 31.

The vaporizer 3 vaporizes the liquid substance by baking. The configuration of the vaporizer 3 will be described in detail later. The pressure sensor 4 is a sensor that senses the pressure inside the tank 31 in the vaporizer 3 and is provided to monitor the pressure.

The second valve 5 is an on-off valve that opens and closes the flow passage of the gas produced as a result of the liquid substance vaporizing in the vaporizer 3 (hereinafter referred to also as the substance gas). With the second valve 5 open, the substance gas produced in the tank 31 in the vaporizer 3 is supplied to the flow rate control device 7 through the gas passage inside the body block 1a. By contrast, with the second valve 5 closed, the substance gas ceases to be supplied to the flow rate control device 7.

The third valve 6 is an on-off valve that opens and closes a flow passage for purging gas. For example, after replacement of the flow rate control device 7, when the flow rate control device 7 alone is purged, while the second valve 5 is left closed, the third valve 6 is opened. In this case, the purging gas supplied through a purge gas flow passage (not illustrated) is introduced, via the third valve 6 and through the gas passage inside the body block 1a, into the flow rate control device 7. On the other hand, the purging of the entire vaporizing system 100 is conducted with the second valve 5 and the third valve 6 both open.

The flow rate control device 7 controls the flow rate of the gas resulting from the liquid substance being vaporized in the vaporizer 3. This flow rate control device 7 is configured, for example, with a mass flow controller. The substance gas output from, while its flow rate is controlled by, the flow rate control device 7 is introduced into an external apparatus (e.g., a semiconductor production apparatus) via a gas outlet port 1c provided in a top part of the body block 1a.

### 2. Configuration of the Vaporized in Detail

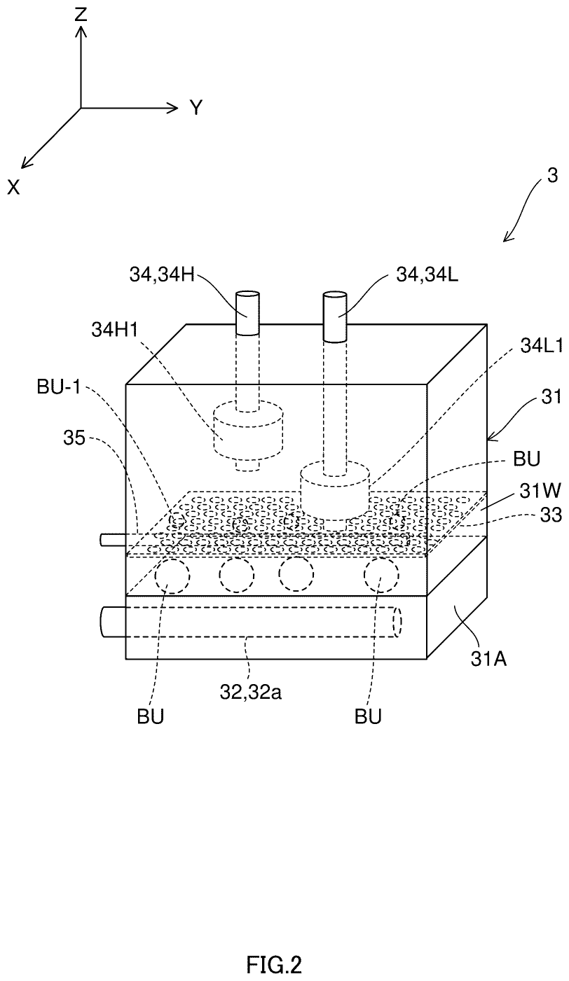

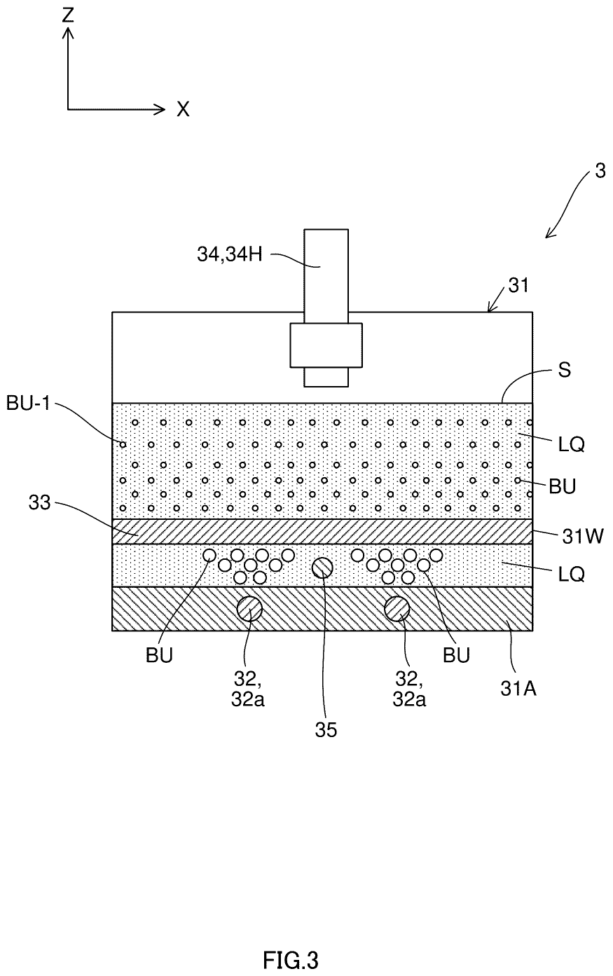

FIG. 2 is a perspective view schematically showing the configuration of the vaporizer 3. FIG. 3 is a sectional view schematically showing the configuration of the vaporizer 3. The vaporizer 3 includes a tank 31, a heater 32, a porous structure 33, a liquid surface sensor 34, and a temperature sensor 35.

The tank 31 is a metal container that stores the liquid substance LQ supplied through the liquid substance supply port 1b (see FIG. 1). The heater 32 is disposed inside the tank 31. In the example in FIGS. 2 and 3, the heater 32 is configured with a cartridge heater 32a and is embedded in a bottom plate portion 31A constituting a bottom part of the tank 31; that is, the tank 31 has a bottom plate portion 31A in which the heater 32 is disposed. The cartridge heater 32a has a structure in which a nichrome wire as a heating element is sheathed in a metal pipe. When the heater is energized to generate heat, the bottom plate portion 31A is heated and the heat of the bottom plate portion 31A is transmitted to the liquid substance LQ. Thus the liquid substance LQ boils and vaporizes to produce gas bubbles BU of the substance gas. As just described, the vaporizer 3 includes a heater 32 that heats the tank 31 (bottom plate portion 31A) to heat the liquid substance LQ (inside).

The porous structure 33 is disposed inside the tank 31. In the example in FIGS. 2 and 3, the porous structure 33 is disposed inside the tank 31, over the bottom plate portion 31A, a predetermined distance away from the bottom plate portion 31A. Thus the porous structure 33 is located over the heater 32 embedded in the bottom plate portion 31A, away from the heater 32. The porous structure 33 is located in contact with a side wall 31W of the tank 31, and is a predetermined distance away from the heating surface (bottom plate portion 31A). The porous structure 33 breaks up and lets pass through it the gas bubbles BU produced as a result of the liquid substance LQ being heated by the heater 32.

The porous structure 33 is disposed at a position where the heat from the heater 32, even if it reaches there, does not produce gas bubbles BU resulting from boiling. That is, in this embodiment, even if the heat from the heater 32 transmits to the porous structure 33, at the position of the porous structure 33, the liquid substance LQ does not boil to produce gas bubbles BU.

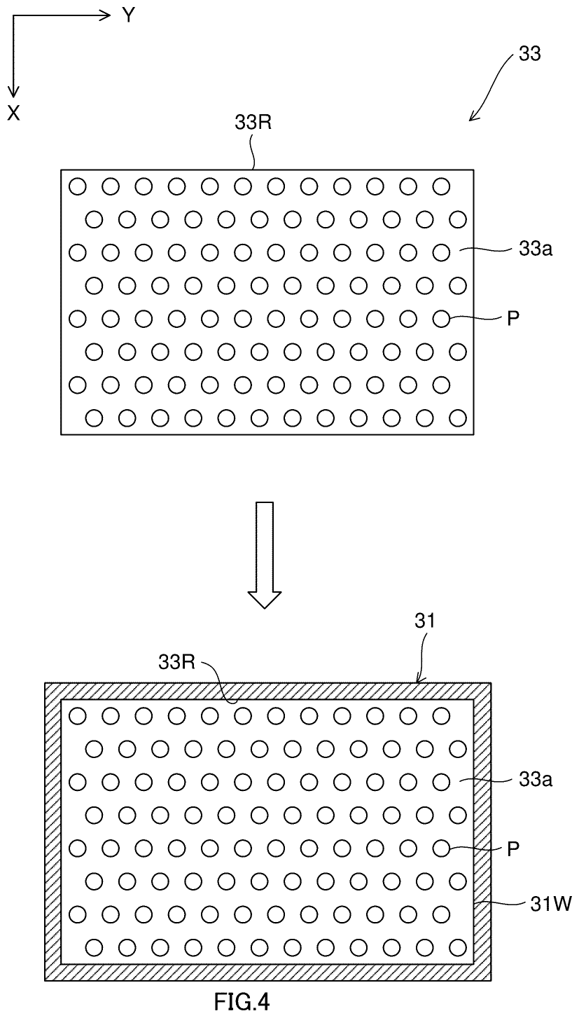

FIG. 4 is a plan view of the porous structure 33, showing it as it is before and after being disposed inside the tank 31. The porous structure 33 is configured with, for example, a porous plate. The porous plate has a structure of a metal flat plate 33a in a rectangular shape as seen in plan view that has a plurality of pores P formed so as to penetrate it along the top-bottom direction. The size (inner diameter) of the pores P is smaller than the size (outer diameter) of the gas bubbles BU produced. Too small pores P may hamper stable vaporization of the liquid substance LQ; thus, preferably, the size of the pores P (in particular, the lower-limit value of their inner diameter) is set to be such as to allow stable vaporization of the liquid substance LQ. The density of the pores P (i.e., the number of pores P per unit area) can be set as appropriate.

The size of the gas bubbles BU produced as a result of the liquid substance LQ being heated varies with the kind of liquid substance LQ used, though they have an outer diameter of around 10 mm regardless of what liquid substance is used. Accordingly, by forming the pores P with, for example, an inner diameter of 1 to 2 mm, it is possible to cope with any liquid substance LQ with a shared (one type of) porous structure 33.

This porous structure 33 is bonded, for example by welding, to the inner surface (side wall 31W) of the tank 31. In the example in FIG. 4, an entire outer edge portion 33R forming the outline of the porous structure 33 as seen in a plan view lies in contact with, and is welded to, the inner surface of the tank 31. Thus, as shown in FIGS. 2 and 3, the porous structure 33 is disposed so as to cover the bottom plate portion 31A of the tank 31 from above.

The liquid surface sensor 34 is a sensor that senses the liquid surface S (see FIG. 3) of the liquid substance LQ in the tank 31 and is also called a float sensor. This liquid surface sensor 34 is configured, as shown in FIG. 2, to include a low-level sensor 34L and a high-level sensor 34H. The low-level sensor 34L has a low-level float portion 34L1 that moves up and down within a predetermined movement range according to the level of the liquid surface S. The high-level sensor 34H has a high-level float portion 34H1 that moves up and down within a predetermined movement range according to the level of the liquid surface S. The movement range of the low-level float portion 34L1 along the top-bottom direction is located lower than the movement range of the high-level float portion 34H1 along the top-bottom direction. These low-level and high-level sensors 34L and 34H are fixed by welding to the upper wall of the tank 31 and are disposed to penetrate the upper wall.

In the embodiment, the first valve 2 (see FIG. 1) is controlled to open and close intermittently by a controller (not illustrated) so that the liquid surface S of the liquid substance LQ in the tank 31 is located between the low-level and high-level float portions 34L1 and 34H1. In this way the supply of the liquid substance LQ into the tank 31 is controlled intermittently.

The temperature sensor 35 is disposed between the heater 32 and the liquid level sensor 34 (in particular, the low-level sensor 34L) to sense the temperature of the liquid substance LQ. The temperature sensor 35 is configured with, for example, a thermocouple. Based on the temperature sensed by the temperature sensor 35, the controller controls the energization of the heater 32 so as to keep the liquid substance LQ in the tank 31 at a temperature at which it vaporizes.

In this configuration where the vaporizer 3 includes the liquid level sensor 34 and the temperature sensor 35, as shown in FIG. 3, the porous structure 33 is disposed between the liquid level sensor 34 and the temperature sensor 35.

In the configuration described above, in the tank 31, as the liquid substance LQ is heated by the heater 32, the liquid substance LQ boils and produces gas bubbles BU. The gas bubbles BU produced are, as they pass through the porous structure 33, finely broken up by the plurality of pores P. Thus, as compared with the gas bubbles BU before passing through the porous structure 33, that is, the gas bubbles BU produced by heating, the gas bubbles BU having passed through the porous structure 33 are smaller (see FIGS. 2 and 3). In this way it is possible to suppress a change in the pressure inside the tank 31 that is caused by formation of the gas bubbles BU. As a result, even in a case where the flow rate control device 7 is disposed on the secondary side of the tank 31 to control the flow rate of the gas of the liquid substance LQ, it is possible to output the gas at a stable flow rate. The configuration of this embodiment is particularly effective in a vaporizer 3 that employs not bubbling vaporization, which produces small bubbles continuously, but heat vaporization, which is prone to an abrupt pressure change such as bumping.

In a configuration where, as in this embodiment, the porous structure 33 is located above the heater 32 away from it, as the liquid substance LQ is heated by the heater 32, gas bubbles BU are necessarily produced between the porous structure 33 and the heater 32. The gas bubbles BU produced then enter the porous structure 33 and, as they pass through the porous structure 33, they are finely broken up. This permits the porous structure 33 to reliably carry out its function of finely breaking up and letting pass through it the gas bubbles BU produced by heating with the heater 32.

The porous structure 33 is disposed so as to cover the bottom plate portion 31A of the tank 31. Thus, as the heater 32 heats, the gas bubbles BU produced in the tank 31 between the bottom plate portion 31A and the porous structure 33 can be directed to the porous structure 33 with no leakage so that they pass through the porous structure 33. That is, all the gas bubbles BU produced by heating with the heater 32 can be guided to the porous structure 33 to be passed through it. It is thus possible to reliably reduce the size of the produced gas bubbles BU with the porous structure 33.

Moreover, the porous structure 33 is disposed between the liquid level sensor 34 and the temperature sensor 35. It is thus possible to reduce the size of the produced gas bubbles BU with the porous structure 33 without hampering the sensing of the liquid surface by the liquid level sensor 34 and the sensing of temperature by the temperature sensor 35. It is also possible to make good use of the limited space between the liquid level sensor 34 and the temperature sensor 35 as a space to arrange the porous structure 33.

The porous structure 33 is a porous plate fabricated by forming a plurality of pores P in a flat plate 33a. Such a porous plate has a simple structure and is easy to produce. The porous structure 33 can thus be obtained easily in the form of a porous plate.

### Modified Configurations of a Vaporizer

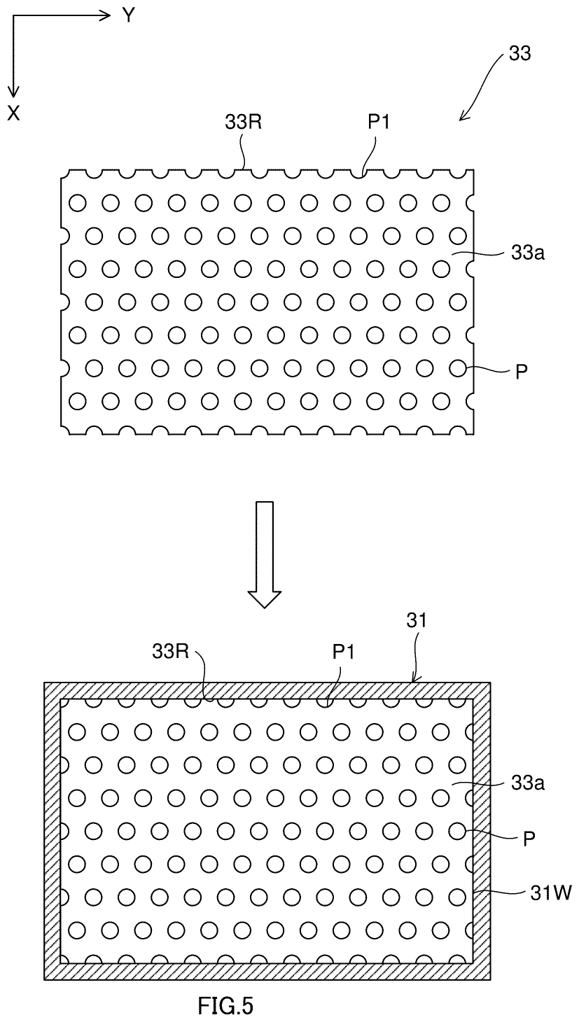

FIG. 5 is a plan view of another porous structure 33, showing it as it is before and after being disposed inside the tank 31. As shown there, the porous structure 33 can be configured to have, in the outer edge portion 33R, openings (cuts) P1 that correspond to parts of the pores P. In that case, the porous structure 33 lies in contact with and is bonded by welding to the inner surface of the tank 31 at parts of the outer edge portion 33R, that is, at the parts of the outer edge portion 33R other than the openings P1. This too can be understood to be a configuration where the porous structure 33 is disposed so as to cover the bottom plate portion 31A of the tank 31.

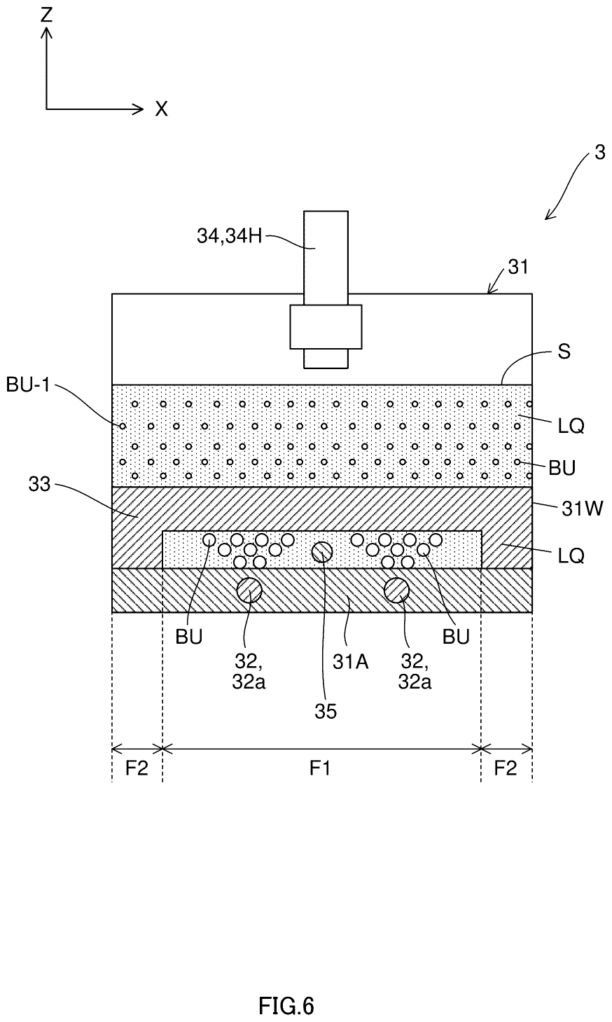

FIG. 6 is a sectional view schematically showing another configuration of the vaporizer 3. As shown there, part of the porous structure 33 can be disposed in contact with the bottom plate portion 31A. Specifically, the porous structure 33 can be configured to have a first region F1 and a second region F2. Here, the first region F1 is a region of the porous structure 33 that is disposed so as to cover the heater 32 and that is located above the bottom plate portion 31A away from it. The second region F2 is a region of the porous structure 33 other than the first region F1 that while being contiguous with the first region F1 lies in contact with the bottom plate portion 31A.

Also with this configuration, the liquid substance LQ present between the first region F1 of the porous structure 33 and the bottom plate portion 31A can be boiled and vaporized by heating with the heater 32 to produce gas bubbles BU and the produced gas bubbles BU can be finely broken up while passing through the porous structure 33 (e.g., the first region F1). Thus the vaporizer 3 of this embodiment can be understood not to be limited to a construction where the entire porous structure 33 is located away from the bottom plate portion 31A (heater 32).

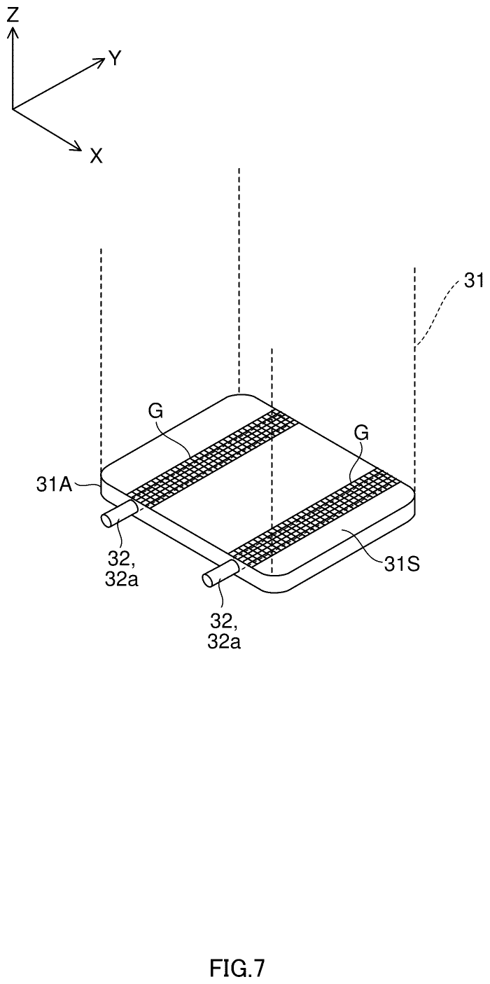

FIG. 7 is a perspective view schematically showing a modified example of the bottom plate portion 31A of the tank 31. The bottom plate portion 31A has a heating surface 31S. The heating surface 31S is a surface that lies in contact with the liquid substance LQ (see FIG. 3) in the tank 31. The heating surface 31S is heated by a heater 32 embedded in the bottom plate portion 31A. The heating surface 31S has grooves G over the heater 32. In the heating surface 31S, the grooves G are formed, for example, in the shape of grids but the grooves G can be formed along one direction (e.g., Y direction in FIG. 7) or in the shape of curved lines.

As the liquid substance LQ is heated by the heater 32, the liquid substance LQ vaporizes from near the heating surface 31S of the bottom plate portion 31A to produce gas bubbles BU. Here, owing to the grooves G formed in the heating surface 31S over the heater 32, fine gas bubbles BU can be produced from the valleys of the grooves G. It is thus possible to reduce the size of the gas bubbles BU themselves that are produced by heating with the heater 32. Thus, by synergy with the breaking-up of gas bubbles BU by the porous structure 33, it is possible to reliably reduce to the size of the gas bubbles BU and to reliably suppress a change in the pressure inside the tank 31.

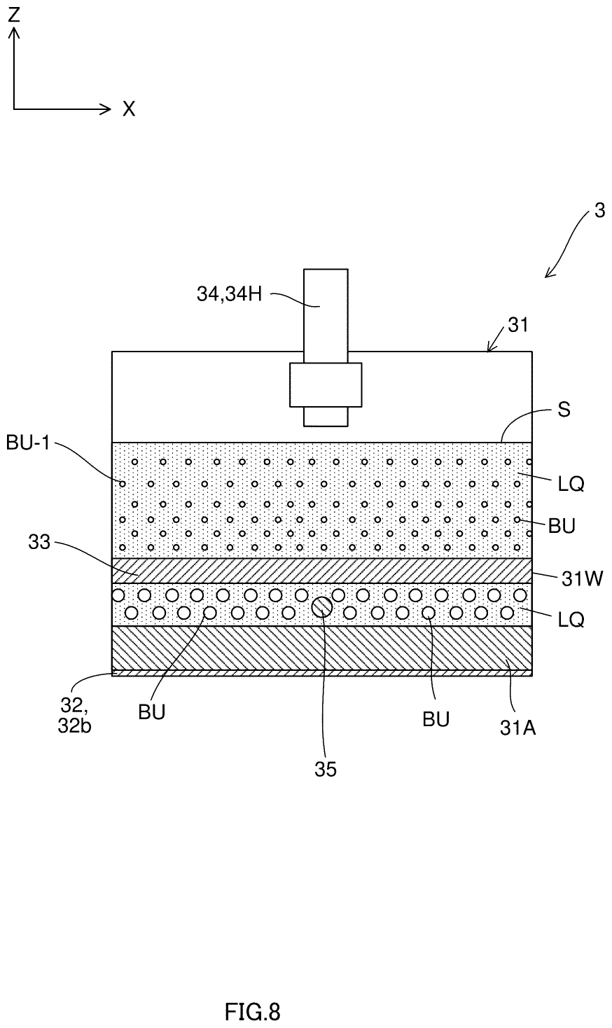

While in the example described above the heater 32 is configured as a cartridge heater 32a of an embedded type (see FIG. 3 etc.), the heater 32 used is not limited to a cartridge heater 32a. FIG. 8 is a sectional view schematically showing yet another configuration of the vaporizer 3. As shown there, the heater 32 can be configure as a rubber heater 32b. In that case, the heater 32 (rubber heater 32b) is provided outside (on the outer face of) the bottom plate portion 31A and heats the tank 31 from below the bottom part of it. Thus the liquid substance LQ in the tank 31 is heated to produce gas bubbles BU.

Also when the rubber heater 32b is used, with the porous structure 33 disposed inside the tank 31, the gas bubbles BU produced as a result of the liquid substance LQ being heated by the rubber heater 32b can be, while passing through the porous structure 33, broken up to reduce the size of the gas bubbles BU. It is thus possible to suppress a change in the pressure inside the tank 31 caused by formation of the gas bubbles BU.

### 4. Supplementary Notes

The porous structure 33 is not limited to a porous plate as used in the embodiment. The porous structure 33 can instead be, for example, a structure with a metal mesh.

According to the present invention, it is possible to suppress a change in the pressure inside a tank caused by formation of gas bubbles.

The embodiment of the present invention described above is in no way meant to limit the scope of the invention, which thus can be carried out with any extensions and modifications made within the spirit of the invention.

The present invention finds application in, for example, vaporizers provided in a stage preceding a semiconductor production apparatus.

What is claimed is:

1. A vaporizer for vaporizing a liquid substance, comprising:
a tank for storing the liquid substance;
a heater for heating the liquid substance by heating the tank; and
a porous structure disposed inside the tank, the porous structure being for breaking up and letting pass therethrough bubbles forming as a result of the liquid substance being heated by the heater.

2. The vaporizer according to claim 1, wherein
the porous structure is located away from the heater.

3. The vaporizer according to claim 1, wherein
the tank has a bottom plate portion on which the heater is disposed, and
the porous structure is disposed so as to cover the bottom plate portion.

4. The vaporizer according to claim 1, wherein
the porous structure is a porous plate having a plurality of pores formed in a flat plate.

5. The vaporizer according to claim 1, further comprising:
a liquid surface sensor for sensing a liquid surface of the liquid substance inside the tank; and
a temperature sensor disposed between the heater and the liquid surface sensor, the temperature sensor being for sensing temperature of the liquid substance,
wherein
the porous structure is disposed between the liquid surface sensor and the temperature sensor.

6. The vaporizer according to claim 2, wherein
the tank has a bottom plate portion on which the heater is disposed, and
the porous structure is disposed so as to cover the bottom plate portion.

7. The vaporizer according to claim 2, wherein
the porous structure is a porous plate having a plurality of pores formed in a flat plate.

8. The vaporizer according to claim 2, wherein
a liquid surface sensor for sensing a liquid surface of the liquid substance inside the tank; and
a temperature sensor disposed between the heater and the liquid surface sensor, the temperature sensor being for sensing temperature of the liquid substance,
wherein
the porous structure is disposed between the liquid surface sensor and the temperature sensor.

9. The vaporizer according to claim 3, wherein
the porous structure is a porous plate having a plurality of pores formed in a flat plate.

10. The vaporizer according to claim 3, wherein
the heater is embedded in the bottom plate portion,
the bottom plate portion has a heating surface that lies in contact with the liquid substance inside the tank and that is heated by the heater, and
the heating surface has a groove over the heater.

11. The vaporizer according to claim 3, wherein
a liquid surface sensor for sensing a liquid surface of the liquid substance inside the tank; and
a temperature sensor disposed between the heater and the liquid surface sensor, the temperature sensor being for sensing temperature of the liquid substance,
wherein
the porous structure is disposed between the liquid surface sensor and the temperature sensor.

12. The vaporizer according to claim 4, wherein
a liquid surface sensor for sensing a liquid surface of the liquid substance inside the tank; and
a temperature sensor disposed between the heater and the liquid surface sensor, the temperature sensor being for sensing temperature of the liquid substance,
wherein
the porous structure is disposed between the liquid surface sensor and the temperature sensor.

13. The vaporizer according to claim 6, wherein
the porous structure is a porous plate having a plurality of pores formed in a flat plate.

14. The vaporizer according to claim 6, wherein
the heater is embedded in the bottom plate portion,
the bottom plate portion has a heating surface that lies in contact with the liquid substance inside the tank and that is heated by the heater, and
the heating surface has a groove over the heater.

15. The vaporizer according to claim 6, wherein
a liquid surface sensor for sensing a liquid surface of the liquid substance inside the tank; and
a temperature sensor disposed between the heater and the liquid surface sensor, the temperature sensor being for sensing temperature of the liquid substance,
wherein
the porous structure is disposed between the liquid surface sensor and the temperature sensor.

16. The vaporizer according to claim 7, wherein
a liquid surface sensor for sensing a liquid surface of the liquid substance inside the tank; and
a temperature sensor disposed between the heater and the liquid surface sensor, the temperature sensor being for sensing temperature of the liquid substance,
wherein
the porous structure is disposed between the liquid surface sensor and the temperature sensor.

17. The vaporizer according to claim 9, wherein
a liquid surface sensor for sensing a liquid surface of the liquid substance inside the tank; and
a temperature sensor disposed between the heater and the liquid surface sensor, the temperature sensor being for sensing temperature of the liquid substance,
wherein
the porous structure is disposed between the liquid surface sensor and the temperature sensor.

18. The vaporizer according to claim 10, wherein
a liquid surface sensor for sensing a liquid surface of the liquid substance inside the tank; and
a temperature sensor disposed between the heater and the liquid surface sensor, the temperature sensor being for sensing temperature of the liquid substance,
wherein
the porous structure is disposed between the liquid surface sensor and the temperature sensor.

19. The vaporizer according to claim 13, wherein
a liquid surface sensor for sensing a liquid surface of the liquid substance inside the tank; and
a temperature sensor disposed between the heater and the liquid surface sensor, the temperature sensor being for sensing temperature of the liquid substance,
wherein
the porous structure is disposed between the liquid surface sensor and the temperature sensor.

20. A vaporizing system comprising:
the vaporizer according to claim 1; and
a flow rate control device for controlling a flow rate of gas resulting from the liquid substance being vaporized by the vaporizer.
